(19) United States
(12) Patent Application Publication
(10) Pub. No.: US 2025/0306650 A1
(43) Pub. Date: Oct. 2, 2025

(54) EXTERNAL POWER SUPPLY MANAGEMENT FOR ENHANCEMENT OF WORKLOAD PERFORMANCE

(71) Applicant: Dell Products L.P., Round Rock, TX (US)

(72) Inventors: FABRICIO ALMEIDA BRONZATI, São Paulo (BR); DHARMESH M. PATEL, Round Rock, TX (US)

(21) Appl. No.: 18/619,710

(22) Filed: Mar. 28, 2024

(51) Int. Cl. G06F 1/18; H05K 7/14

(52) U.S. Cl. CPC G06F 1/189; H05K 7/1492

(57) ABSTRACT

Methods, systems, and devices for managing performance of workloads by hardware components housed in a power supply free chassis of a rack system are disclosed. To manage the performance, a request may be obtained to perform a workload of the workloads. Based on the request, a power risk assessment for rail mounted power systems of the rack system, and a power consumption estimate for the workload, may be used to make a determination. This determination may be made regarding whether to accept the request based on the power risk assessments, the power consumption estimate, and acceptable risk criteria. In a first instance of the determination where the request is accepted, the workload may be performed using at least a portion of the hardware components. In a second instance of the determination where the request is not accepted, the request may be rejected.

### FIELD

Embodiments disclosed herein relate generally to management of workload performance by devices in data processing systems. More particularly, embodiments disclosed herein relate to systems and methods for management of external power components for power supply free chassis in a rack system.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a data processing system in accordance with an embodiment.

FIGS. 2A-2D show diagrams illustrating a rack system in accordance with an embodiment.

FIG. 2E shows a data flow diagram illustrating a method for obtaining a risk assessment for a power supply free chassis of a rack system in accordance with an embodiment.

FIG. 2F shows a data flow diagram illustrating a method for external power supply management for enhancement of workload performance in accordance with an embodiment.

FIG. 3 shows a flow diagram illustrating a method for managing performance of workloads by hardware components housed in a power supply free chassis of a rack system in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing performance of workloads that provide, at least in part, computer implemented services. To provide the services, a data processing system may include any number of hardware components (e.g., storage devices, memory modules, processors, etc.) housed in power supply free chassis for performing the workloads.

To provide the computer implemented services, workloads may be performed by various hardware components of the data processing system. By doing so, these hardware components may facilitate various functionalities of the data processing system (e.g., 100).

To perform the workloads, the hardware components may consume power. For example, the hardware components may consume direct current to perform computations.

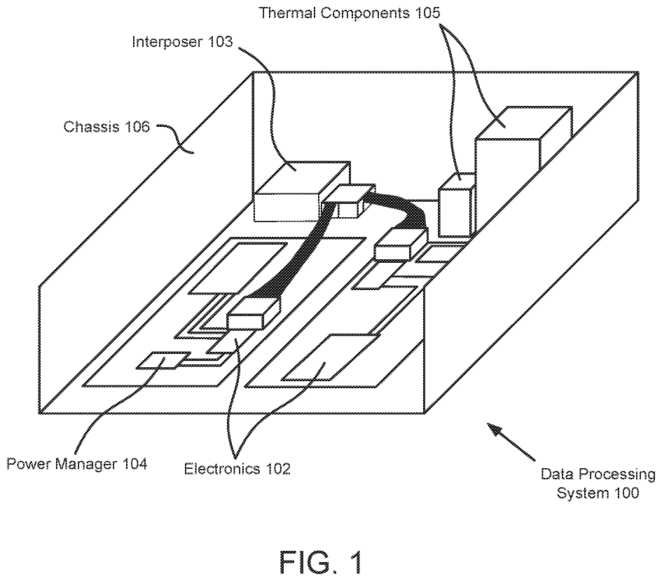

If the hardware components are not provided with sufficient power, then the hardware components may be unable to perform workloads as desired. Consequently, the system of FIG. 1 may be unable to provide the desired computer implemented services.

In general, embodiments disclosed herein relate to systems, devices, and methods for improving the likelihood of data processing systems being able to provide desired computer implemented services. To do so, for example, a power manager of the data processing system may be assessed for power availability, and workload placement decisions to the data processing systems may be made based on the power availability assessments. Consequently, when a workload is placed with a data processing system, the workload may be more likely to be completed.

It will be appreciated that power components such as power supply units may be positioned outside of, and operably connected to, data processing systems. Due to the external placement of the power components, chassis 106 may herein be referred to as a power supply free chassis.

Thus, externally placed power components for providing power to the power supply free chassis may be managed to, for example, optimize performance of workloads facilitated by hardware components dependent on the externally placed power components.

In an embodiment, a method of managing performance of workloads that provide, at least in part, computer implemented services is provided, the workloads being performed by hardware components housed in power supply free chassis of a rack system.

The method may include obtaining a request to perform a workload of the workloads; in response to obtaining the request: obtaining power risk assessments for rail mounted power systems of the rack system; obtaining a power consumption estimate for the workload; making a determination regarding whether to accept the request based on the power risk assessments, the power consumption estimate, and acceptable risk criteria; in a first instance of the determination where the request is accepted: performing the workload using at least a portion of the hardware components; and in a second instance of the determination where the request is not accepted: rejecting the request.

The rack system may be adapted for placement of the power supply free chassis in a high-density computing environment that may include data processing systems, the rack system comprising: a rack for housing at least a portion of the data processing systems and adapted to hold at least one chassis, and the rack comprising at least one vertical rail; and a rail mounted power system adapted to mount directly to a single vertical rail of the at least one vertical rail.

The rail mounted power system may include: a power distribution unit adapted to obtain rack system level power and distribute, using the rack system level power, power supply level power; and at least one power supply adapted to obtain a portion of the power supply level power and distribute, using the power supply level power, logic level power to the at least one chassis.

The rack system may further include the power supply free chassis.

The power supply free chassis does not house any power components for converting power from the power supply level power to the logic level power, and wherein operation of the hardware components depends on obtaining power from the rail mounted power system.

The rail mounted power system may be further adapted to participate in provisioning of redundant power to the power supply free chassis in cooperation with at least one other rail mounted power system.

The method may further include prior to obtaining the request, and for a rail mounted power system of the rail mounted power systems: obtaining health information for the rail mounted power system; obtaining a power connectivity map that indicates, at least, dependence of data processing systems of the rack system on the rail mounted power system for power.

Obtaining a power risk assessment of the power risk assessments for the rail mounted power system using the health information, the power connectivity map, and a risk assessment system.

The acceptable risk criteria may require decreasing levels of power risk assessment as the level of power consumption increases for the workload to be accepted.

Obtaining the power risk assessment may include identifying, using a power connectivity map, a portion of the rail mounted power systems that impacts an ability of the rail mounted power system to provide power.

In an embodiment, a non-transitory media is provided. The non-transitory media may include instructions that when executed by a processor cause, at least in part, the computer-implemented method to be performed.

In an embodiment, a data processing system is provided. The data processing system may include the non-transitory media and a processor and may, at least in part, perform the method when the computer instructions are executed by the processor.

Turning to FIG. 1, a diagram illustrating a data processing system in accordance with an embodiment is shown. The data processing system shown in FIG. 1 may provide computer implemented services. The computer implemented services may include any type and/or quantity of computer implemented services. For example, the computer implemented services may include data storage services, instant messaging services, database services, and/or any other type of service that may be implemented with a computing device.

To provide the computer implemented services, workloads may be performed by various hardware components of the data processing system. By doing so, these hardware components may facilitate various functionalities of the data processing system (e.g., 100).

To perform the workloads, the hardware components may consume power. For example, the hardware components may consume direct current to perform computations.

If the hardware components are not provided with sufficient power, then the hardware components may be unable to perform workloads as desired. Consequently, the system of FIG. 1 may be unable to provide the desired computer implemented services.

In general, embodiments disclosed herein relate to systems, devices, and methods for improving the likelihood of data processing systems being able to provide desired computer implemented services. To do so, the data processing systems may be assessed for power availability, and workload placement decisions to the data processing systems may be made based on the power availability assessments. Consequently, when a workload is placed with a data processing system, the workload may be more likely to be completed.

To provide the above noted functionality, data processing system 100 of FIG. 1 may include electronics 102, interposer 103, power manager 104, thermal components 105, and/or chassis 106. Each of these components is discussed below.

Electronics 102 may include various types of hardware components such as processors, memory modules, storage devices, communications devices, and/or other types of devices. Any of these hardware components may be operably connected to one another using circuit card traces, cabling, connectors, etc. that establish electrical connections used to transmit information between the hardware components and/or transmit power to the hardware components. For example, electronics 102 may include interposer 103 and/or power manager 104. Each of these is discussed below.

Interposer 103 may route power provided by power components (e.g., power supply units (PSUs)) to electronics 102. To do so, interposer 103 may include an electrical interface that receives power at a first connection (e.g., via some power cables and/or connection pins) and spreads at least a portion of that power to any number of different connections (e.g., leading to the various hardware components of electronics 102).

Although not explicitly shown in FIG. 1, power components such as the PSUs may be positioned outside of, and operably connected to, data processing system 100. Due to the external placement (e.g., with respect to chassis 106) of the power components, chassis 106 may herein be referred to as a power supply free chassis.

For additional information regarding the power components and their placement with regard to data processing system 100, see further below.

Power manager 104 may provide workload placement services for data processing system 100. To provide the workload placement services, power manager 104 may (i) identifying sources of power for data processing system 100 (e.g., PSUs), (ii) assess the health of the sources of the power, (iii) identify responsibilities for supply of power by the sources of power, (iv) obtaining workload requests, (v) identifying power requirements of the workload requests, (vi) using the health of the sources of the power and the responsibilities for the sources of the power to assess whether to accept the workload requests, and (vii) accepting or rejecting workload requests accordingly, and performing acceptable workloads to contribute to desired computer implemented services provided by the system of FIG. 1.

Power manager 104 may be implemented using hardware and/or software components. For example, power manager 104 may be implemented using a management controller, a microcontroller, and/or other type of programmable logic device that is able to perform the functionality of power manager 108 described herein when so programmed to do so.

Thermal components 105 may thermally manage any of the hardware components of data processing system 100. For example, thermal components 105 may include fans, heat sinks, and/or other types of devices usable to thermally manage the hardware components as operation of the hardware components generates heat.

Any of the hardware components (power components excluded) of data processing system 100 may be positioned within an interior of chassis 106. For example, chassis 106 may include an enclosure in which physical structures of electronics 102 (e.g., processors, memory, power manager 104, etc.), interposer 103, and/or thermal components 105 (e.g., fans, heat sinks, etc.) may be positioned.

For example, to provide its functionality, chassis 106 may be implemented with a form factor compliant (e.g., a ½U sled) enclosure usable to integrate data processing system 100 into a high-density computing environment, such as a rack mount chassis management system (herein referred to as a “rack system”).

Therefore, chassis 106 may facilitate placement and management of electronics 102 and/or other components in a computing environment (e.g., the power components, mentioned previously). For example, to facilitate placement and management of PSUs for providing power to data processing system 100, chassis 106 may be positioned in a rack of the rack system, and operably connected to a rail mounted power system integrated with a single vertical rail of the rack system.

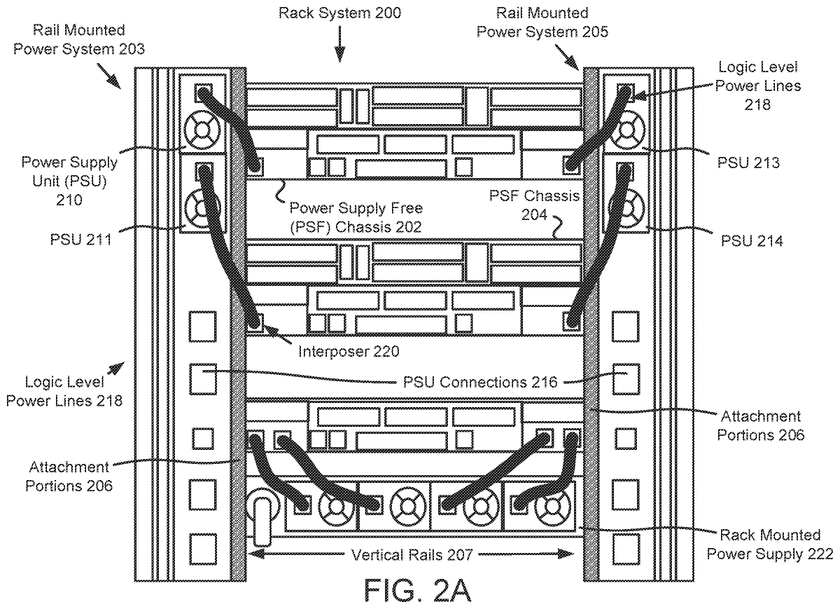

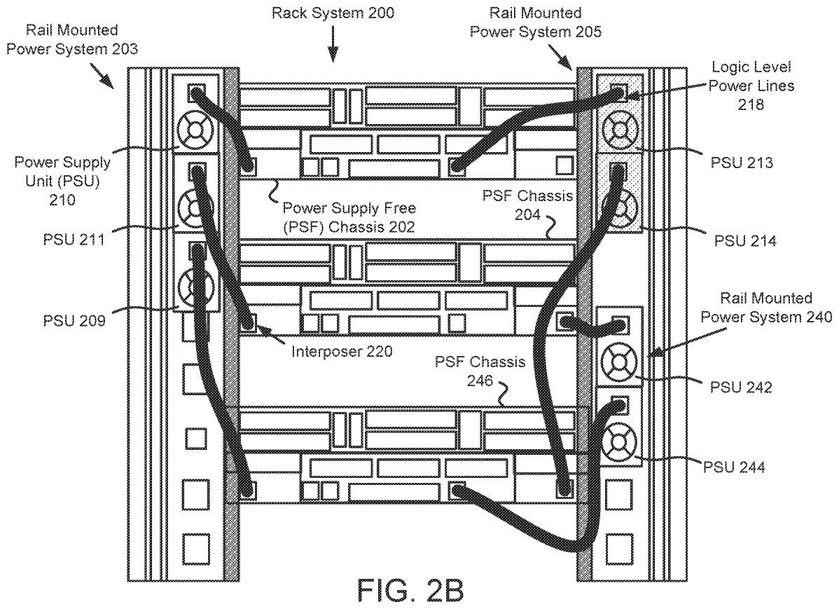

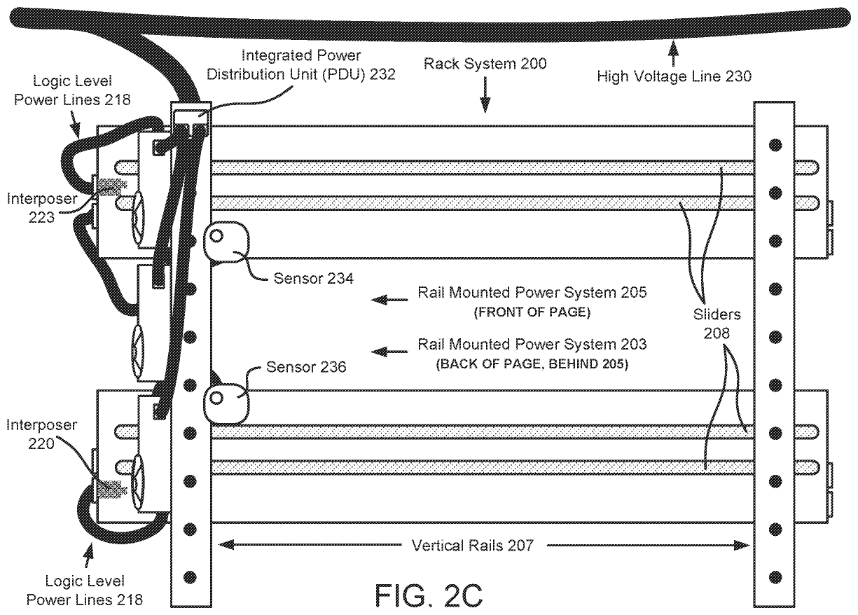

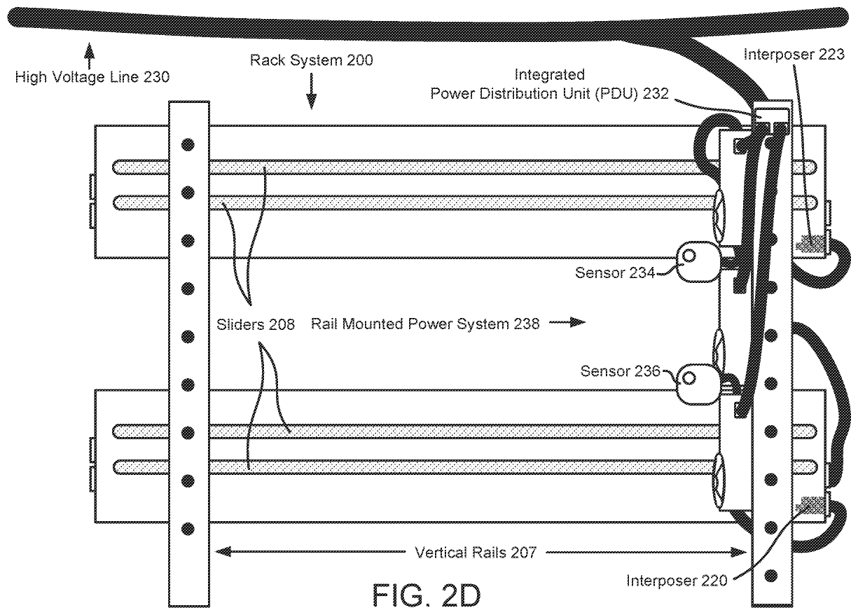

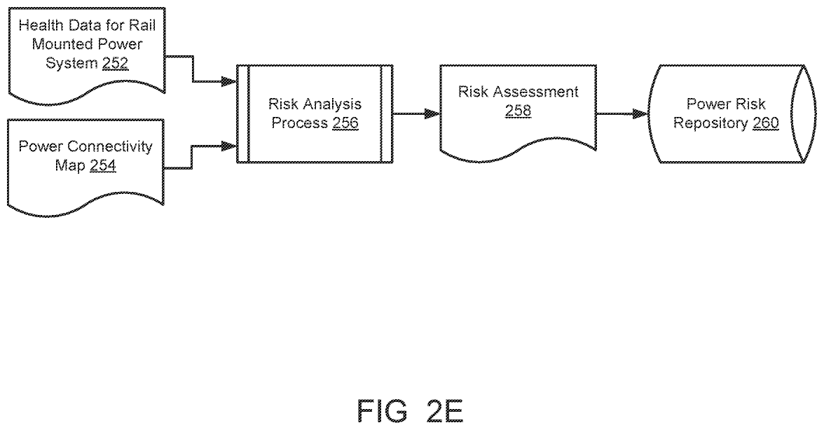

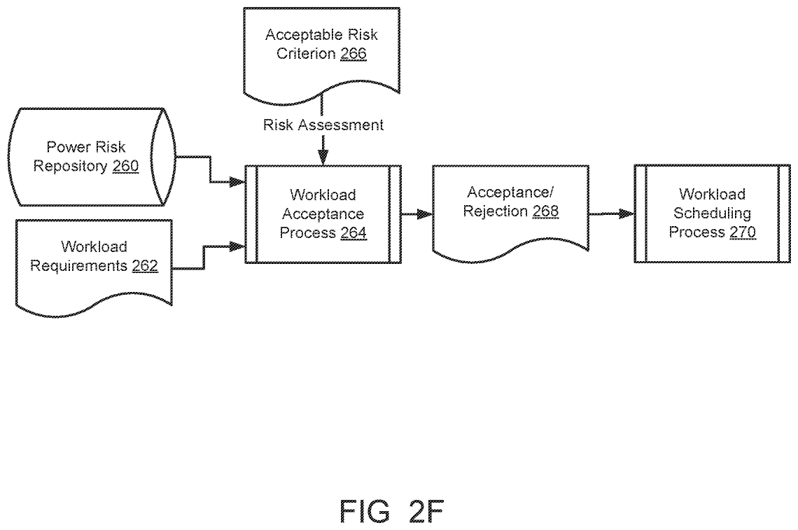

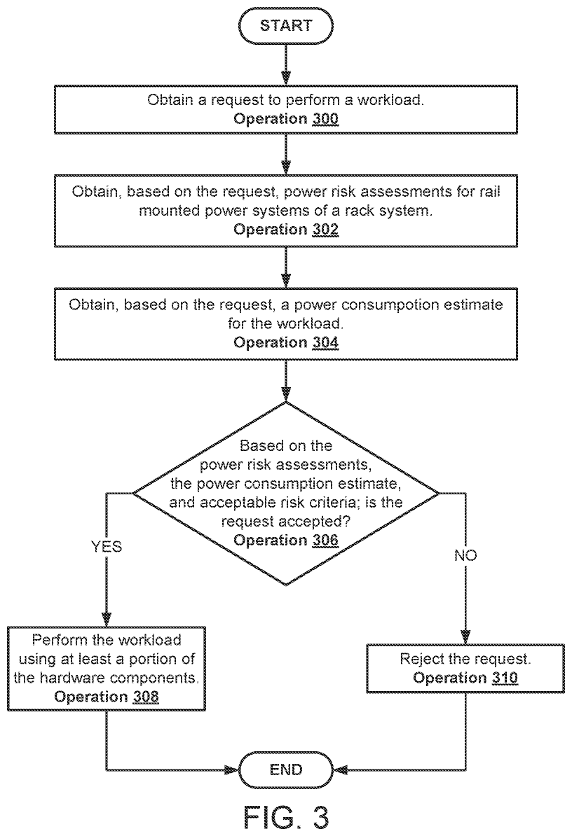

Refer to FIGS. 2A-2D below for additional detail regarding the rail mounted power system, rack system, and/or power supply free chassis (e.g., 106). Refer to FIGS. 2A-3 below for additional detail regarding power management for enhancing workload performance.

Thus, by managing power (e.g., by assessing power availability) and making workload placement decisions based on, for example, the power availability assessments, the likelihood of data processing systems being able to provide desired computer implemented services may be improved. Therefore, and as previously mentioned, when a workload is placed with a data processing system, the workload may be more likely to be completed.

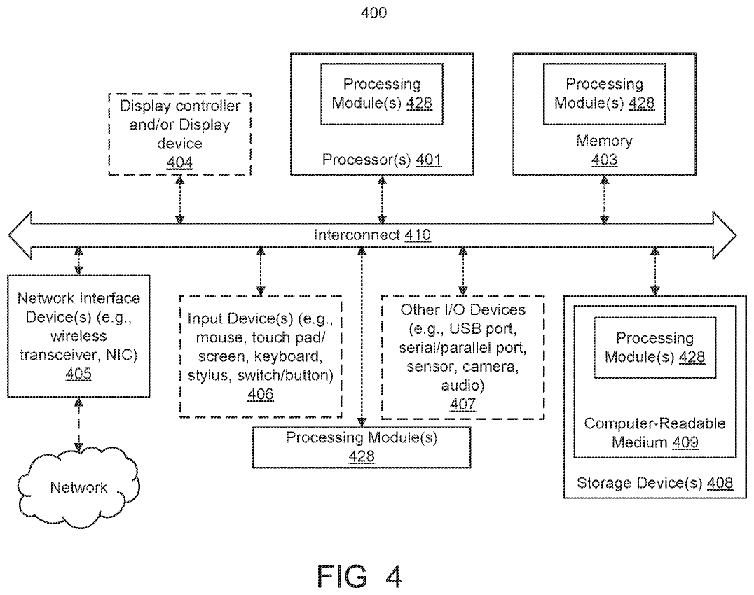

Data processing system 100 (and/or components of a rack system in which data processing system 100 is positioned) may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system. For additional details regarding computing devices, refer to FIG. 4.

While illustrated in FIG. 1 with a limited number of specific components, a data processing system may include additional, fewer, and/or different components without departing from embodiments disclosed herein.

As noted above, the data processing system of FIG. 1 may include a power supply free chassis due to a lack of power components positioned within the interior of chassis 106. Additionally, the data processing system of FIG. 1 may be placed with a rack of a rack system and provided power using a rail mounted power system integrated with a singular vertical rail of the rack system.

FIGS. 2A-2D show diagrams illustrating examples of power supply free chassis positioned with a rack system that includes a rail mounted power system in accordance with an embodiment.

Turning to FIG. 2A, a first diagram illustrating a rack system (e.g., 200) in accordance with an embodiment is shown. The viewpoint of FIG. 2A may be of a rear side of rack system 200, the viewpoint being from directly behind the rack system and facing a same direction as a front side on the rack system.

This rack system may allow for compact and organized storage (e.g., placement) of any number of chassis (e.g., data processing systems), thereby allowing utilization of various systems to provide the computer implemented services.

To provide its functionality, the rack system may include power supply free (PSF) chassis 202 and 204, and rail mounted power system 203 and 205. Each of the two chassis may be positioned on a rack of the rack system. For example, the rack system may further include attachment portions 206 that are lined up along a vertical axis of vertical rails 207, where each attachment portion of attachment portions 206 may be used to fixedly attach a PSF chassis to the rack.

The rail mounted power systems may each be mounted to a respective single vertical rail of the rack system. For example, rail mounted power system 203 may include power supply unit (PSU) 210 and 211, and rail mounted power system 205 may include PSU 213 and 214. As previously discussed, power supply units (PSU's) may be positioned outside of a chassis, resulting in a PSF chassis (e.g., PSF 202 and/or 204). To facilitate this positioning, rack system 200 may include any number of connections such as PSU connections 216. For example, PSU 210-214 may be operably connected to various connections of PSU connections 216 to be provided power transmissions (e.g., “power supply level power”, discussed further below) facilitated by rail mounted power systems 203 and 205. PSU 210-214 may, in turn, provide the power transmissions further along the rail mounted power systems as “logic level power” (discussed further below) to at least a portion of the hardware components and/or additional hardware resources.

To provide their functionalities, PSU connections 216 may be implemented by sockets formed along the rails of rack system 200 that include operable connections for various power transmissions to be facilitated between the rail mounted power systems and any chassis positioned in a rack of rack system 200. In some cases, PSU connections 216 may only restrict movement of a PSU to a limited portion of the exterior by facilitating fixed attachments between each of the PSU and corresponding connections of PSU connections 216. Thus, PSU connections 216 may facilitate various levels (e.g., various degrees) of attachment between each of the PSU and the rail mounted power systems.

Regardless of what level of attachment may be facilitated by PSU connections 216 (so long as the operable connections are facilitated), logic level power lines 218 may direct the power transmissions for the hardware components and/or the additional hardware resources, mentioned previously. For example, logic level power lines 218 may operably connect directly and/or indirectly (e.g., via PSU connections 216) to a PSU of the PSU's. In doing so, logic level power lines 218 may provide a path through which the power transmissions may traverse during operation of either chassis.

To provide their functionality, logic level power lines 218 may be implemented by cabling, connectors, etc. that establish electrical connections used to transmit power to the hardware components and/or the additional hardware resources.

However, the power transmitted via logic level power lines 218 may have an alternating current (AC) (e.g., may be AC power), and therefore may not be natively usable by the hardware components and/or the additional hardware resources. To modify the power transmission so that the hardware components and/or the additional hardware resources may natively use the power, the power transmission may be passed through one or more interposers (e.g., 220).

For example, some of logic level power lines 218 may direct power transmissions from PSU 211 of rail mounted power system 203, through interposer 220, and to the hardware components and/or the additional hardware resources. In doing so, the hardware components and/or the additional hardware resources may natively use the power output from interposer 220, interposer 220 modifying the power transmission to output a direct current (DC) rather than an AC.

To modify the power from an AC to a DC, interposer 220 may route power from the PSU 211 to at least a portion of the hardware components and/or the additional hardware resources (e.g., electronics 102, discussed previously). For example, interposer 220 (e.g., 107 in FIG. 1) may include an electrical interface that receives power at a first connection (e.g., via some power cables and/or connection pins operably connected to at least a portion of logic level power lines 218) and spreads at least a portion of that power to any number of different connections (e.g., that lead to the various hardware components of, for example, electronics 102, and/or the additional hardware resources).

By integrating PSU 211-214 as shown in FIG. 2A, rail mounted power system 203 and 205 may provide power management in a more efficient manner than, for example, rack mounted power supply 222.

For example, to integrate rack mounted power supply 222 with rack system 200, rack mounted power supply 222 may require placement in a position (e.g., in a rack, and/or in at least a portion of collective positions otherwise referred to as “available chassis space”) normally usable by various chassis integrated with rack system 200 to provide computer implemented services.

However, by positioning rack mounted power supply 222 in the position, the available chassis space in rack system 200 may be limited. Consequently, the quantity of chassis capable of being positioned with the rack system may be limited. By limiting the quantity of chassis (and therefore, hardware components therein), a quality, quantity, and/or type of the various functionalities on which the computer implemented services depend may also be limited. Thus, a quality, quantity, and/or type of the computer implemented services may be limited by the limited available chassis space provided by rack system 200.

By using rail mounted power systems, rather than rack mount power supply, Power components may provide power to the interior of PSF chassis (from an exterior of the PSF chassis) without limiting a quality, quantity, and/or type of the computer implemented services.

For additional information regarding management of power transmissions, refer to FIGS. 2B-3.

Turning to FIG. 2B a second diagram illustrating a rack system (e.g., 200) in accordance with an embodiment is shown. The viewpoint of FIG. 2B may be of a rear side of rack system 200, the viewpoint being from directly behind the rack system and facing a same direction as a front side on the rack system.

As discussed above, when making workload placement decisions, the health and other characteristics of rail mounted power systems that supply power to electronics in chassis may be considered. To do so, the level of redundancy, responsibility, and health of the rail mounted power systems may be monitored and used in such decisions.

To monitor the redundancy of power being supplied to chassis, the power managers of each of the chassis may (i) identify the power supplies and host rail mounted power systems that supply power to the chassis, (ii) distribute the obtained information to other power managers, and (iii) update a power connectivity map using the obtained information. The power connectivity may indicate which chassis are powered by corresponding power supplies of rack mounted power systems. Thus, the reliance on each power supply of the rack mounted power systems may be identified.

For example, in FIG. 2B and as previously discussed, rack system 200 may include rail mounted power systems 203 and 205. Additionally, rack system 200 may further include rail mounted power system 240, with which PSU 242 and 244 may be positioned. Rack system 200 may also include a third PSF chassis such as PSF chassis 246, and rail mounted power system 203 may further include PSU 209.

Each PSU positioned with a rail mounted power system may be operably connected to any of the chassis to provide power, at least in part, to the operably connected chassis. For example, PSU 242 may be operably connected to PSF chassis 204 while PSU 244 may be operably connected to PSF chassis 246.

It will be appreciated that any of the chassis may be redundantly powered by multiple rail mounted power systems. For example, PSF chassis 246 may be redundantly powered by rail mounted power systems 203, 205, and 240. More specifically, PSF chassis 246 may be redundantly powered by PSU 209, 214, and 244. Additionally, for example, PSF chassis 204 may be redundantly powered by PSU 211 and 242, and PSF 203 may be redundantly powered by PSU 210 and 213.

Additionally, it will be appreciated that any of the rail mounted power systems may power multiple PSF chassis. To do so, a rail mounted power system may be simultaneously and operably connected to the multiple PSF chassis. For example, rail mounted power system 240 may power PSF chassis 204 and 246, rail mounted power system 205 may power PSF chassis 202 and 246, and/or rail mounted power system 203 may power PSF chassis 202, 204, and 246.

By having redundant power, chassis may perform workloads with a decreased likelihood of interruption. For example, assume a malfunction occurs with rail mounted power system 205. This malfunction may delay and/or prevent PSU 213 and 214 entirely from providing sufficient power to a chassis. However, because of redundant power that was available to PSF chassis 202 and 246, rail mounted power system 203 may increase power output to provide sufficient power to both PSF chassis 202 and 246, and rail mounted power system 240 may increase power output to provide sufficient power to PSF 246.

Thus, the level of redundancy may be indicated by the power connectivity map.

To monitor the responsibility of the power supplies, the power connectivity map and the states of the rail mounted power supplies may be used to ascertain the level of responsibility on each rail mounted power system. For example, prior to the malfunction mentioned above, and assuming that rail mounted power systems 203 and 205 were in similar if not a same state, rail mounted power system 203 may have had an equal level of responsibility as rail mounted power system 205. However, post malfunction, the level of responsibility may increase for rail mounted power system 203 due to PSF chassis 202 having a complete reliance on rail mounted power system 203 for power to operate. Similarly, a responsibility level of rail mounted power system 246 may increase, however, not as much as rail mounted power system 203 due to there still being redundant power available to PSF 246 post-malfunction.

By monitoring the level of responsibility, a decision regarding what hardware components may be better equipped to perform specific workloads without exceeding workload capacity (e.g., when no additional work may be performed on top of already performing workloads).

To monitor the health of the rail mounted power systems, the power managers of each of the chassis may (i) receiving information regarding the health of each rail mounted power system that supplies power to the chassis, (ii) distribute the obtained information to other power managers, and (iii) update the connectivity map. For example, health of a rail mounted power system may be self-reported (e.g., may be provided by the rail mounted power system) to power managers of corresponding chassis, and the power managers take this information into account when making workload decisions.

By monitoring the health of the rail mounted power systems, additional information regarding a rail mounted power system (e.g., temperature, maximum power output, available power, average power consumption) may be used to define the rail mounted power system's workload capacity.

Using the above information, workload placement decisions may be made that are more likely to result in timely serviced workloads, and less likely to be interrupted. For example, the workload placement decisions may preferentially cause workloads to be placed with chassis that are (i) serviced by lower responsibility rack mounted power systems, and (ii) are serviced by rack mounted power systems that have higher health status. Consequently, the health and/or responsibilities of the rack mounted power systems may be less likely to cause workloads to be, for example, paused, aborted, etc. due to lack of power being supplied to a host chassis.

Turning to FIG. 2C, a third diagram illustrating the rack system (e.g., 200) in accordance with an embodiment is shown. The viewpoint of FIG. 2C may be from a right side of the rack system, the rear side facing a left of the page and the front side facing a right of the page.

As discussed above, components of rail mounted power system 203 and/or 205 (e.g., PSUs 210-214, logic level power lines 218, interposer 220 (and/or 223), integrated power distribution unit (PDU) 232, high voltage line 330, and/or other components) may be used to manage power provided for the PSF chassis. For example, these components, at least in part, may modify at least a portion of the power transmission provided to either PSF chassis (e.g., 202 and/or 204) for powering the hardware components. Thus, operation of the PSF chassis may be enabled.

For example, assume a power providing service directs a power transmission towards a location at a client's request. This power transmission may be transmitted a distance away from the power providing service via powerlines (e.g., high voltage line 230), and thus, may be provided with an alternating current (AC) for efficient transit to the requested location. When this power transmission reaches the requested location, rail mounted power system 205, for example, may obtain the AC (referred to as “rack system level power” at this point of the power transmission) via high voltage line 230.

To do so, the AC may be directed through high voltage power line 230 towards PDU 232 of rail mounted power system 205. PDU 232 may (i) obtain the AC, and (ii) distribute the power transmission to a number of power supply units integrated with rail mounted power system 205 (e.g., 213-214). In doing so, PDU 232 may modify the rack system level power to provide “power supply level power”, mentioned previously with regard to FIG. 2A.

As rail mounted power system 205 continues to facilitate the power transmission, the logic level power may be provided to interposer 220 where the AC of the power transmission is modified to provide a DC to the hardware components (the DC of the power transmission thereby enabling the native usability of the power transmission by the hardware components.

To further manage power provided for the PSF chassis, the rail mounted power systems may further include sensors (e.g., 234 an/or 236, previously mentioned with regard to FIG. 1). These sensors may be used, at least in part, for safety processes regarding power transmissions. For example, the sensors may be used as part of a method for decreasing a likelihood of compromise of the hardware components and/or compromise of workload performance caused by an interruption of power transmissions.

For example, assume the client of the power providing service is at the requested location to provide regularly scheduled maintenance for rack system 200. To service PSF chassis 202 (the top PSF chassis), the client may slide PSF chassis 202 along sliders 208 (to the right of the page) in order to pull PSF chassis 203 out of rack system 200 from the front side of rack system 200. However, rail mounted power systems 203 and 205 may still be operably connected to PSF chassis 202 by logic level power lines 218.

Consequently, as PSF chassis 202 is pulled an unacceptable distance (e.g., a distance that is longer than the maximum distance in which logic level power lines 218 may extend safely and without disconnecting) out through the front side, the logic level power lines 218 may break and/or otherwise disconnect, thereby interrupting any power transmissions being directed to PSF chassis 202.

Such interruption of power allows for compromise of data processing systems of the rack system. For example, the compromise may include data loss or corruption and/or an electrical shortage, leading to a power spike, thereby causing damage to the PSUs, the hardware components, the additional hardware resources, and/or other components.

To decrease a likelihood of the compromise caused by an interruption of power transmissions, the sensors (e.g., 234 and/or 236) may be used to identify whether the power supply free chassis is positioned in an acceptable position. For example, the power components may be adapted to limit distribution of power while the power supply free chassis is not in the acceptable position. For example, the acceptable position may be any position that is a distance shorter than the maximum distance, mentioned previously.

For additional information regarding the sensors, refer to FIG. 2D, below.

Turning to FIG. 2D a fourth diagram illustrating the rack system (e.g., 200) in accordance with an embodiment is shown. The viewpoint of FIG. 2D may be the same viewpoint as shown in FIG. 2C.

As noted previously, the rail mounted power system may be mounted on any single vertical rail of the rack enclosure. For example, the rail mounted power system may be integrated with rack system 200 in various ways as shown in FIGS. 2A-2D.

For example, while mounted on vertical rails 207 in FIG. 2C (rails on a rear side of rack system 100), rail mounted power systems 203 and 205 may also be mounted on vertical rails that are on a front side of rack system 200 (e.g., 238), as shown in FIG. 2D.

Thus, a rack system may include the components discussed in FIGS. 2A-2D, a rail mounted power system being mounted to a single vertical rail of the rack system, and the rack system may use the mounted rail mounted power system to manage power for a power supply free chassis of a data processing system.

To further clarify embodiments disclosed herein, data flow diagrams in accordance with an embodiment are shown in FIGS. 2E-2F. In these diagrams, flows of data and processing of data are illustrated using different sets of shapes. A first set of shapes (e.g., 252, 254, etc.) is used to represent data structures, a second set of shapes (e.g., 256, etc.) is used to represent processes performed using and/or that generate data, and a third set of shapes (e.g., 260, etc.) is used to represent large scale data structures such as databases.

Turning to FIG. 2E, a first data flow diagram in accordance with an embodiment is shown. The first data flow diagram may illustrate data used in, and data processing performed in, assessing risk (e.g., a level of risk that ranges from low risk to high risk) associated with power usage/consumption for performing workloads. For example, and based on the assessment, a high risk associated with power provided to a data processing system may indicate a high likelihood of compromise of the data processing system. For example, the high risk may be associated with an increased likelihood of shortages, power surges, and/or other electrical failures resulting in an inability to provide hardware components of the data processing system with power. Consequently, without power, the hardware components may be unable to perform the workloads.

To decrease the likelihood of compromise of the hardware components, risk assessments (e.g., 258) may be obtained for (at least a portion of) the external power supplies with regard to each workload requiring processing. Each of these risk assessments may provide an indication of a likelihood of compromise of the hardware components and/or respective workloads, the compromise posing a threat to the performance of workloads.

To obtain the risk assessments, health data (e.g., the health discussed with regard to FIG. 2B) for rail mounted power system 252 and power connectivity map 254 (discussed previously) may be used in risk analysis process 256.

Power connectivity map 254 may be implemented with a data structure specifying what power components are attached (for operable connections) to what hardware components. Therefore, a power component of the power components may power a limited number of the hardware components.

Health data for rail mounted power system 252 may include, but is not limited to, various health states of the power components attached to a single vertical rail. These health states may include but are not limited to temperature, a date of manufacture, a minimum power output, a maximum power output, available power, average power consumption over time, and an average deterioration rate for component efficiency since the date of manufacture.

Once obtained, health data for rail mounted power system 252 and power connectivity map 254 may be used as input for risk analysis process 256. By doing so, risk analysis process 256 may output risk assessment 258. Assuming risk assessment 258 is a single assessment (e.g., rather than a collection of assessments), risk assessment 258 may be placed in power risk repository 260 and/or another type of available storage space.

Power risk repository 260 may be used for making determinations regarding how the workloads may be managed. For additional information regarding how the workloads may be managed based on power risk repository 260, refer to FIG. 2F, below.

Turning to FIG. 2F, a second data flow diagram in accordance with an embodiment is shown. The second data flow diagram may illustrate data used in, and data processing performed in, management of performance of workloads.

To manage the performance of the workloads, workload acceptance process 264 may be performed. During workload acceptance process 264, new requests for workloads may be evaluated to determine whether to accept or reject the requests. To make the determinations, (i) workload requirements 262 for a workload may be obtained, (ii) acceptable levels of risk for the workload may be obtained, (iii) for a data processing system that may service the request, information regarding the health and level of responsibility of the rack mounted power systems that supply power to the data processing system may be obtained, (iv) the aforementioned information may be analyzed to identify whether the data processing system present an acceptable of risk for the workload, and (v) the determination may be made based on whether the risk is acceptable or unacceptable.

To obtain workload requirements 262, the request for performing the workload may be analyzed. The analysis may yield workload requirements 262. Workload requirements 262 may indicate a quantity of power, a duration of time, and/or other requirements of performing a workload.

To obtain acceptable levels of risk for the workload, the acceptable levels of risk may be read from storage, may be obtained from another device, may be dynamically generated, and/or via other methods. For example, to obtain the acceptable levels of risk from storage, a lookup data structure may be stored in the storage. The lookup data structure may associate different types of workloads with different levels of acceptable risk. The type of the workload may be used as a key to perform a lookup in the lookup data structure. Once obtained, the acceptable levels of risk may be stored in memory and/or storage as acceptable risk criterion 266.

To obtain the health and level of responsibility for rail mounted power systems that supply power to the data processing system, power risk repository 260 may be queried. To query the power risk repository 260, an identifier for the data processing system may be provided. Power risk repository 260 may return the level of responsibility and health in response to the query.

To analyze the aforementioned information, a relative level of risk may be obtained. To do so, the relative level of risk may be read from storage, obtained from another device, dynamically generated, and/or obtained via other methods.

For example, the relative level of risk may be dynamically generated by ingesting the level of responsibility, the health, and the workload requirements into a formula, inference model, or other type of entity that may provide the relative level of risk as a function of this aforementioned information.

To determine whether the relative level of risk is acceptable, the relative level of risk may be compared to the acceptable levels of risk. If the relative level of risk is within the acceptable levels of risk, the request may be accepted. Otherwise, the request may be rejected. The outcome of the determination may be stored as acceptance/rejection 268.

Once acceptance/rejection 268 is obtained, workload scheduling process 270 may be performed. During workload scheduling process 270, if the workload is accepted as specified by acceptance/rejection 268, then the workload may be scheduled for performance. Otherwise, the request is rejected, and the workload is not scheduled for performance.

To perform workload scheduling process 270, characteristics of the requested workload may be identified (e.g., as discussed with regard to workload requirements 262). For example, performance of the workload may require no more than an hour to complete successfully. The queue may be checked for a range of time that is equal to or greater than the no more than an hour. If the queue has the range available between other workloads scheduled in the queue, the requested workload may be scheduled in a first range available. If the queue does not have the range available, then the requested workload may be scheduled at the end of the queue,

Thus, using the data flows shown in FIGS. 2E-2F, power may be managed to enhance performance of workloads.

Any of the processes illustrated using the second set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor-based devices (e.g., computer chips).

Any of the data structures illustrated using the first and third set of shapes may be implemented using any type and number of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

As discussed above, the components of FIGS. 1-2F may perform various methods to manage performance of workloads by data processing systems. FIG. 3 illustrates a method that may be performed by the components of FIGS. 1-2F.

In the diagram discussed below and shown in FIG. 3, any operations may be repeated, performed in different orders, and/or performed in parallel with, or partially overlapping in time with, other operations.

Turning to FIG. 3, a flow diagram illustrating a method for managing performance of workloads by hardware components (housed in a power supply free chassis of a rack system) in accordance with an embodiment is shown.

The method may be performed by, for example, a power manager, rail mounted power system (integrated with a single vertical rail of the rack system), and/or any other entity.

It will be appreciated that although described with regard to being integrated with a single vertical rail of the rack system, the rail mounted power system may be capable of integrating with any single vertical rail of the rack system.

At operation 300, a request is obtained to perform a workload. The request may be obtained by hardware resources (e.g., the hardware components) of the data processing system communicating with other devices operably connected to the data processing system (e.g., via communication channels). For example, a user of the data processing system may initiate an action set to provide a functionality of a device operably connected to the data processing system (e.g., using a mouse and keyboard). By initiating the action set, a request for performing the workload associated with the functionality may be provided to a processor of the data processing system.

The action set may depend on a level of power consumption necessary and may include, for example, executable computer code on which the action set is based.

Thus, this communication may facilitate a traversal of data indicative of the action set to be performed, the action set being dependent on a level of power consumption necessary for performing the action set to perform the workload.

At operation 302, power risk assessments are obtained for rail mounted power systems of a rack system based on the request. The power risk assessments may be obtained by (i) obtaining health information for the rail mounted power system, and (ii) obtaining a power connectivity map that indicates, at least, dependence of the power supply free chassis of the rack system on the rail mounted power system for power, and (iii) using the health information and the power connectivity map with a risk assessment system, to obtain a power risk assessment.

The health information for the rail mounted power system may be obtained by accessing, for example, a repository (e.g., a log) of data regarding characteristics of the power components. For example, a device manager may access and/or otherwise facilitate electrical transmissions with a power supply unit of the power supplies to obtain information regarding the power supply unit such as maximum power capacity, minimum power capacity, etc. Additionally, for example, a rate of power consumption may be logged in long term storage throughout a utilization of the power supply unit.

The power connectivity map, as noted above, may indicate dependence of the power supply free chassis on the rack system on the rail mounted power system for power. For example, the power connectivity map may indicate that specific hardware components of the power supply free chassis are dependent on consumption of specific power supply level power from, in some cases, specific power components.

The risk assessment system may include acceptable risk criteria to be implemented with a rule set defining how the health information and/or the power connectivity map may be accessed, read, interpreted, modified, and/or otherwise used. Thus, the health information and the power connectivity map may be obtained with the risk assessment system.

At operation 304, a power consumption estimate is obtained for the workload based on the request. The power consumption estimate may be obtained by identifying subprocesses required to complete the workload. For example, a workload may include 10 instances of multiplication processes, 5 instances of division processes, and 25 instances of a look up process using a database. Events regarding these subprocesses may already have logs defining levels of power used (e.g., and/or how long a level of power was used), and those logs may be used to determine a power consumption estimate for any and/or all the power supplies available.

At operation 306, a determination is made regarding whether the request is accepted based on the power risk assessments and acceptable risk criteria. The determination may be made by comparing the power risk assessments with each of the rules defined by the acceptable risk criteria, previously mentioned.

For example, the acceptable risk criteria may indicate a requirement for 65 watts for a duration of at least 3 hours to perform the workload. Therefore, if the power risk assessment for the power supply unit provides less than 65 watts at any given time, and/or may not be expected to be able to provide 65 watts or more for more than 3 hours, the request may not be accepted.

If determined that the request is accepted, then the method may proceed to operation 308. Otherwise, the method may proceed to operation 310.

At operation 308, the workload is performed using at least a portion of the hardware components. The workload may be performed by executing the executable computer code on which the action set depends. For example, the executable computer code may be processed by a processor of the power supply free chassis, thereby causing at least a portion of the hardware components to facilitate the action set to perform the workload.

The method may end following operation 308.

Returning to operation 306, the method may proceed to operation 310.

At operation 310, the request is rejected. The request may be rejected by not providing the executable computer code to the processor and/or otherwise preventing the action set, and thus, preventing performance of the workload.

It will be appreciated that although mentioned with regard to preventing performance of a workload, rejecting the request may include, for example, modifying a workload schedule (e.g., queue) for any of the hardware components and/or any of the power supplies.

The method may end following operation 310.

Therefore, externally placed power components for providing power to the power supply free chassis may be managed to, for example, optimize performance of workloads facilitated by hardware components dependent on the externally placed power components.

For example, by depending on the acceptable risk criteria to allow for management of workloads, the management may be based on characteristics of the workloads and characteristics of the power components. Therefore, a likelihood of damage caused by a lack of power available and/or caused by an excess of power directed for performing the workload may be decreased.

Additionally, by using the method above, externally placed power components may be managed while providing a means for placement of additional hardware components within an interior of the power supply free chassis made usable by an absence of power component in the interior of the power supply free chassis.

Thus, a likelihood of compromise from, thereby increasing a type, quantity and/or quality of computer implemented services to be provided and decreasing a likelihood of compromise of the hardware components caused by the power directed to the power supply free chassis (e.g., a loss of power during performance of workloads).

Any of the components illustrated in and/or discussed with regard to FIGS. 1-2F may be implemented with and/or used in conjunction with one or more computing devices. For example, the security bezel may be used to secure a chassis in which components of a data processing system may be positioned (e.g., processors, memory, etc.). Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing performance of workloads by hardware components housed in a power supply free chassis of a rack system, the method comprising:
obtaining a request to perform a workload of the workloads; and
in response to obtaining the request:
obtaining power risk assessments for rail mounted power systems of the rack system;
obtaining a power consumption estimate for the workload;
making a determination regarding whether to accept the request based on the power risk assessments, the power consumption estimate, and acceptable risk criteria;
in a first instance of the determination where the request is accepted:
performing the workload using at least a portion of the hardware components; and
in a second instance of the determination where the request is not accepted:
rejecting the request.

2. The method of claim 1, wherein the rack system is adapted for placement of the power supply free chassis in a high-density computing environment comprising data processing systems, the rack system comprising:
a rack for housing at least a portion of the data processing systems and adapted to hold at least one chassis, and the rack comprising at least one vertical rail; and
a rail mounted power system adapted to mount directly to a single vertical rail of the at least one vertical rail.

3. The method of claim 2, wherein the rail mounted power system comprises:
a power distribution unit adapted to obtain rack system level power and distribute, using the rack system level power, power supply level power; and
at least one power supply adapted to obtain a portion of the power supply level power and distribute, using the power supply level power, logic level power to the at least one chassis.

4. The method of claim 3, wherein the rack system further comprises:
the power supply free chassis.

5. The method of claim 4, wherein the power supply free chassis does not house any power components for converting power from the power supply level power to the logic level power, and wherein operation of the hardware components depends on obtaining power from the rail mounted power system.

6. The method of claim 5, wherein the rail mounted power system is further adapted to participate in provisioning of redundant power to the power supply free chassis in cooperation with at least one other rail mounted power system.

7. The method of claim 1, further comprising:
prior to obtaining the request,
and for a rail mounted power system of the rail mounted power systems:
obtaining health information for the rail mounted power system;
obtaining a power connectivity map that indicates, at least, dependence of data processing systems of the rack system on the rail mounted power system for power; and
obtaining a power risk assessment of the power risk assessments for the rail mounted power system using the health information, the power connectivity map, and a risk assessment system.

8. The method of claim 7, wherein the acceptable risk criteria require decreasing levels of power risk assessment as a level of power consumption increases for the workload to be accepted.

9. The method of claim 1, wherein obtaining the power risk assessment comprises:
identifying, using a power connectivity map, a portion of the rail mounted power systems that impact an ability of the rail mounted power system to provide power.

10. A non-transitory machine-readable medium having instructions stored therein, which when executed by a processor, cause the processor to perform operations for managing performance of workloads by hardware components housed in a power supply free chassis of a rack system, the operations comprising:
obtaining a request to perform a workload of the workloads; and
in response to obtaining the request:
obtaining power risk assessments for rail mounted power systems of the rack system;
obtaining a power consumption estimate for the workload;
making a determination regarding whether to accept the request based on the power risk assessments, the power consumption estimate, and acceptable risk criteria; and
in a first instance of the determination where the request is accepted:
performing the workload using at least a portion of the hardware components; and
in a second instance of the determination where the request is not accepted:
rejecting the request.

11. The non-transitory machine-readable medium of claim 10, wherein the rack system is adapted for placement of the power supply free chassis in a high-density computing environment comprising data processing systems, the rack system comprising:
a rack for housing at least a portion of the data processing systems and adapted to hold at least one chassis, and the rack comprising at least one vertical rail; and
a rail mounted power system adapted to mount directly to a single vertical rail of the at least one vertical rail.

12. The non-transitory machine-readable medium of claim 11, wherein the rail mounted power system comprises:
a power distribution unit adapted to obtain rack system level power and distribute, using the rack system level power, power supply level power; and
at least one power supply adapted to obtain a portion of the power supply level power and distribute, using the power supply level power, logic level power to the at least one chassis.

13. The non-transitory machine-readable medium of claim 12, wherein the rack system further comprises:
the power supply free chassis.

14. The non-transitory machine-readable medium of claim 13, wherein the power supply free chassis does not house any power components for converting power from the power supply level power to the logic level power, and wherein operation of the hardware components depends on obtaining power from the rail mounted power system.

15. The non-transitory machine-readable medium of claim 14, wherein the operations further comprise:
wherein the rail mounted power system is further adapted to participate in provisioning of redundant power to the power supply free chassis in cooperation with at least one other rail mounted power system.

16. A data processing system, comprising:
a processor; and
a memory coupled to the processor to store instructions, which when executed by the processor, cause the processor to perform operations for managing performance of workloads by hardware components housed in a power supply free chassis of a rack system, the operations comprising:
obtaining a request to perform a workload of the workloads; and
in response to obtaining the request:
obtaining power risk assessments for rail mounted power systems of the rack system;
obtaining a power consumption estimate for the workload;
making a determination regarding whether to accept the request based on the power risk assessments, the power consumption estimate, and acceptable risk criteria; and
in a first instance of the determination where the request is accepted:
performing the workload using at least a portion of the hardware components; and
in a second instance of the determination where the request is not accepted:
rejecting the request.

17. The data processing system of claim 16, wherein the rack system is adapted for placement of the power supply free chassis in a high-density computing environment comprising data processing systems, the rack system comprising:
a rack for housing at least a portion of the data processing systems and adapted to hold at least one chassis, and the rack comprising at least one vertical rail; and
a rail mounted power system adapted to mount directly to a single vertical rail of the at least one vertical rail.

18. The data processing system of claim 17, wherein the rail mounted power system comprises:
a power distribution unit adapted to obtain rack system level power and distribute, using the rack system level power, power supply level power; and
at least one power supply adapted to obtain a portion of the power supply level power and distribute, using the power supply level power, logic level power to the at least one chassis.

19. The data processing system of claim 18, wherein the rack system further comprises:
the power supply free chassis.

20. The data processing system of claim 19, wherein the power supply free chassis does not house any power components for converting power from the power supply level power to the logic level power, and wherein operation of the hardware components depends on obtaining power from the rail mounted power system.
